(19) United States
(12) Patent Application Publication
(10) Pub. No.: US 2014/0117509 A1
(43) Pub. Date: May 1, 2014

(54) Metal Deposition with Reduced Stress

(71) Applicant: INFINEON TECHNOLOGIES AG, Neubiberg (DE)

(72) Inventors: Manfred Schneegans, Vaterstetten (DE); Juergen Foerster, Tegernheim (DE); Bernhard Weidgans, Bernhardswald (DE); Norbert Urbansky, Dresden (DE); Tilo Rotth, Dresden (DE)

(73) Assignee: INFINEON TECHNOLOGIES AG, Neubiberg (DE)

(21) Appl. No.: 13/661,810

(22) Filed: Oct. 26, 2012

(51) Int. Cl. H01L 21/768; C23C 14/34; H01L 23/48; H01L 21/3205; H01L 29/06

(52) U.S. Cl. 257/629; 438/652; 204/192.1; 204/298.02; 257/E21.295; 257/E29.022; 257/E23.01; 257/E21.575

(57) ABSTRACT

Various techniques, methods and devices are disclosed where metal is deposited on a substrate, and stress caused by the metal to the substrate is limited, for example to limit a bending of the wafer.

### BACKGROUND

For manufacturing electronic devices, for example semiconductor electronic devices, substrates like semiconductor substrates are provided with metal contacts to establish an electrical connection between semiconductor devices or circuits formed on the substrate and the outside world. In other cases, metal interconnects are formed electrically coupling different parts of semiconductor devices on the substrate.

To manufacture such metal contacts, usually metal is deposited on a surface of the substrate such that a metal layer is formed on the substrate. Such a metal layer may cause stress, for example compressive or tensile stress, to the substrate, which may lead to an undesired bending of the substrate. This problem has become more pronounced in recent years as thinned semiconductor wafers, for example semiconductor wafers grinded to a thickness of less than 100 μm, have been increasingly used. As the thinning reduces the mechanical strength of the semiconductor wafers, such a bending due to metal deposition becomes more pronounced.

### BRIEF DESCRIPTION OF THE DRAWINGS

FIG. 1 is a schematic diagram illustrating semiconductor processing;

FIG. 2 is a diagram of a sputtering apparatus usable in some embodiments and operating in a first pressure range;

FIG. 3 is a diagram of a substrate with a metal coating deposited in the first pressure range;

FIG. 4 is a diagram of the sputtering apparatus of FIG. 2 operating in a second pressure range;

FIG. 5 is a schematic view of a substrate coated with a metal deposited in the second pressure range;

FIG. 6 is a schematic diagram of a metal-coated substrate according to an embodiment;

FIG. 7 is a schematic diagram of a metal-coated substrate according to an embodiment;

FIG. 8 is a flowchart illustrating a method according to an embodiment;

FIG. 9 is a flowchart illustrating a method according to an embodiment;

FIG. 10 is a flowchart illustrating a method according to an embodiment; and

FIG. 11 is a flowchart illustrating a method according to an embodiment.

### DETAILED DESCRIPTION OF ILLUSTRATIVE EMBODIMENTS

Embodiments will be described in detail referring to the accompanying drawings in the following detailed description. It is to be noted that this description is to be taken as being illustrative only and is not construed as limiting the scope of the application.

Features of different embodiments may be combined with each other unless noted otherwise. On the other hand, describing an embodiment with a plurality of features is not to be construed as indicating that all these features are necessary for practicing the invention, as other embodiments may comprise less features and/or alternative features.

Elements shown in the drawings are not necessarily to scale with each other, but are depicted in a manner to give a clear understanding of the respective embodiments. Furthermore, describing a method as a series of actions or events is not to be construed as indicating that the actions or events have to be performed in the order described, but may be performed also in any other order, including an order where actions or events described take place concurrently with each other.

While embodiments will be described using specific materials as example, it should be noted that application of the techniques disclosed herein is not restricted to the materials described, and other materials may also be used within the scope of this application.

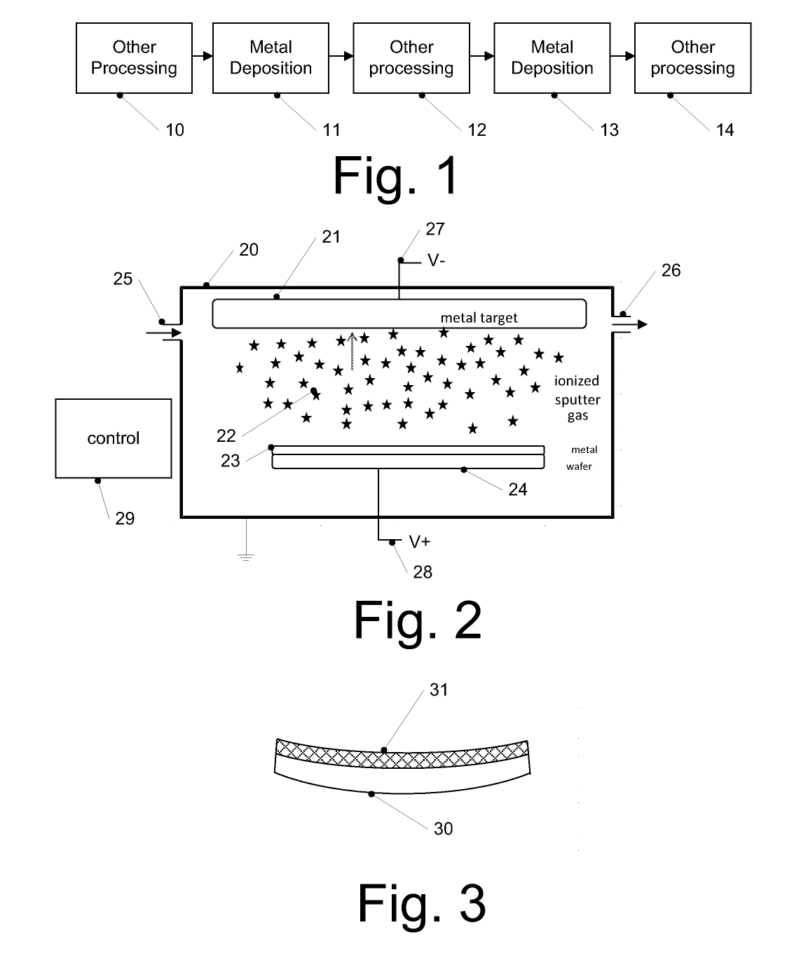

Turning now to the figures, in FIG. 1 a process flow for example for processing semiconductor wafers and manufacturing semiconductor devices is schematically shown as an example environment where embodiments may be used. In the example process shown in FIG. 1, some processing (labeled “other processing”) is performed at 10, followed by a metal deposition at 11, followed by further processing at 12, followed another metal deposition at 13, followed by yet further processing at 14. In case of semiconductor processing, the processing at 10, 12 and/or 14 may comprise conventional processing steps like lithography steps (optical lithography, e-beam lithography and the like), ion implantation processes (for example for doping), etching processes and the like.

Metal deposition processes 11 and 13 may comprise for example depositing metal on a front side of a wafer (i.e., a side of a semiconductor wafer where semiconductor devices are formed) or depositing metal on a backside of a wafer. It should be noted that other processes may only comprise a single metal deposition process or more than two metal deposition processes. Also, metal deposition processes may comprise depositing different metals immediately after each other without any other processing there between. Techniques, devices and methods described in the following may be applicable to one or more of metal deposition processes 11, 13 or to any other processes where metal is deposited on a substrate, not being limited to the process illustrated in FIG. 1.

Metal deposition in embodiments may for example be performed by sputtering, although it is not limited thereto, and other metal deposition techniques also may be used. In FIG. 2, a sputtering device useable in embodiments is schematically shown operating in a first pressure range.

The apparatus of FIG. 2 comprises a sputter chamber 20 into which a sputter gas like Argon may be introduced via an inlet 25 and exhausted via an exhaust 26. Other sputtering gases than Argon, for example other noble gases, are also possible. In sputter chamber 20, a metal target 21 made of or coated with a metal which is to be deposited on a wafer 24 or other substrate is provided. The metal target is biased with a negative voltage V− via a biasing connector 27. The metal target may for example be made of or coated with copper (Cu) for copper disposition on wafer 24. However, other metals may also be used in embodiments, like aluminum, silver, gold or tin. In some embodiments, metals used may have an elastic component and a plastic component.

Wafer 24 may be positively biased by a voltage V+ via a biasing connector 28.

When operated at comparatively high sputter gas pressures, for example in sputter gas pressure of approximately 4 mTorr (0,53 Pa), the sputtering is mainly due to ionized sputter gas ions 22 (for example Argon ions) impinging on metal target 21 thus ejecting metal atoms from metal target 21 which deposit on wafer 24 and form a metal layer 23 on wafer 24. Wafer 24 may for example be a semiconductor wafer like a silicon wafer. It should be noted that in other embodiments instead of semiconductor wafers any other substrates may be used. In some embodiments, wafer 24 may be a thinned wafer, i.e., a wafer grinded to a thickness of 100 μm or below, which may be mounted on a further substrate like a glass substrate. In other embodiments, wafer 24 may be a thicker wafer, for example a semiconductor wafer with a thickness of 400 μm or higher. For a pressure of a first pressure range as shown in FIG. 1, metal atoms ejected from metal target 21 may reach wafer 24 undergoing a random walk as they may collide with ions 22 or atoms of the sputter gas.

Furthermore, the sputter apparatus of FIG. 2 comprises a control unit 29, for example a computer, via which processing conditions, in particular the pressure of the sputter gas, may be controlled to a desired range.

In the first pressure range depicted in FIG. 2, for example a pressure of approximately 4 mTorr, the metal layer, for example copper layer, thus formed may exert a tensile stress on the wafer, for example a silicon wafer, leading to a bending or warping of the wafer for example at room temperature as shown schematically in FIG. 3. In FIG. 3, a wafer like a silicon wafer is labeled 30, while a metal layer like a copper layer is labeled 31.

In FIG. 4, the sputter apparatus of FIG. 2 is shown operating in a second pressure range differing from the first pressure range of FIG. 2, in particular a pressure range with lower pressure, the second pressure range being supported by a higher magnetic field than the first pressure range. For example, the pressure of the sputter gas may be set via control unit 29 to be below 0.1 mTorr (13.33 mPa).

Here, only few ionized sputter gas ions 22 (symbolized by filled stars) are present. On the other hand, ejected metal atoms collide with the gas ions in the chamber 20, in particular a plasma room thereof, leading to self-ionization of the metal, thus forming a self-ionizing plasma. Metal ions thus formed are symbolized by open stars 40 in FIG. 4. Those metal ions may impinge on target 21 in a ballistic manner, i.e., with higher speed, and sputter off (eject) metal atoms with higher kinetic energy forming a more dense metal layer 23 on wafer 24 than in case of FIG. 2. Such a metal layer, for example copper layer, may exert a compressive stress on a wafer, for example a silicon wafer, thus leading to a bending of the wafer in the opposite direction than the first pressure range of FIG. 2.

This is schematically shown in FIG. 5, where a metal layer 51 is deposited on a wafer 50 leading to a bending of wafer 50 in the opposite direction compared to FIG. 3. In the following, the bending of FIG. 3 will be referred to as concave bending, whereas the bending of FIG. 5 will be referred to as convex bending, the terms concave and convex referring to the surface on which the respective metal layer is deposited.

Therefore, as clear from the explanations with respect to FIGS. 2-5, depending on the pressure of the sputter gas a metal layer exerting a tensile stress on a substrate or a metal layer exerting a compressive stress on a substrate may be formed. In embodiments, these phenomena are used to provide metal layers which exert a reduced or minimized stress on a substrate, thus reducing or eliminating bending of the substrate.

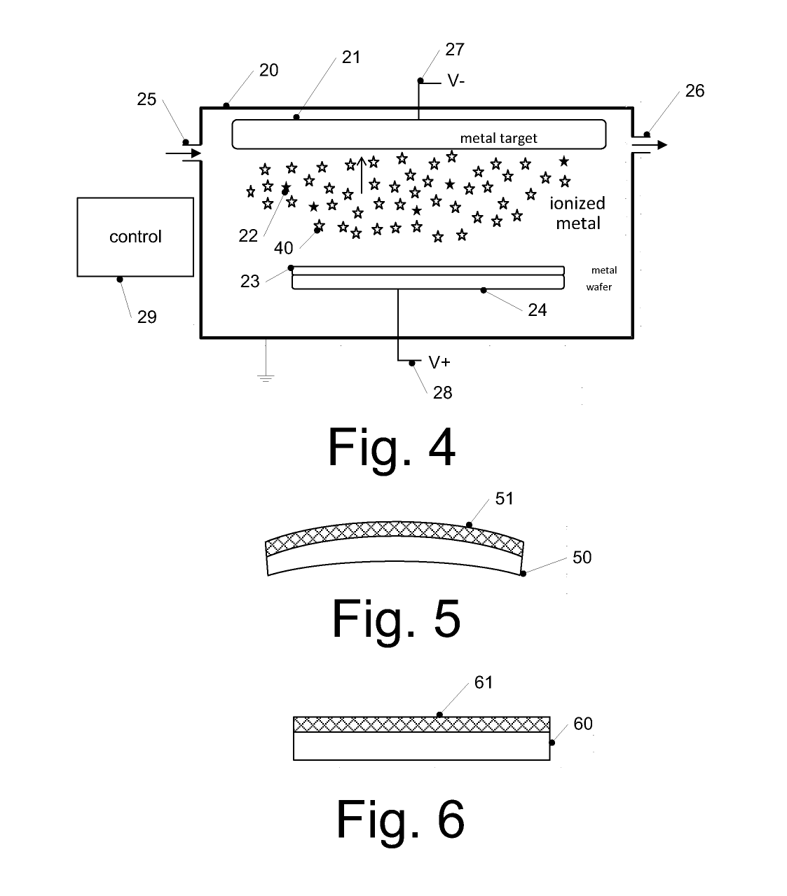

A corresponding substrate with a metal layer is shown in FIG. 6. Here a metal layer 61, for example a copper layer, is deposited on a substrate 60 in a manner that the stress exerted by the metal layer 61 on substrate 60 is limited, e.g., reduced, and therefore bending is minimized. It should be noted that depending on the application it is not necessary to bring the stress and the bending to zero, but some stress and/or bending may be acceptable. For example, for a thin 8 inch wafer with a thickness below 100 μm, for example about 60 μm, a bending below 200 μm, or a bending below 100 μm may be acceptable. The measures for the bending given above are the “height” of the highest point of the substrate when the substrate is placed on a flat surface.

For example, therefore a bending in embodiments may be less than 0.002, preferably less than 0.001 times the diameter of the substrate.

In embodiments, various approaches may be employed to limit the stress caused by the metal layer to acceptable values. In a first approach, the pressure may be selected appropriately between the first and second pressure ranges illustrated with respect to FIGS. 2 and 4, respectively, for example to a pressure about 0.2 mTorr or 0.3 mTorr, to deposit a metal layer with intermediate properties between the compressive properties of FIG. 5 and the tensile properties of FIG. 3. In another embodiment, a metal layer as shown in FIG. 5 exerting compressive strain is deposited and then annealed at a predetermined temperature, for example a temperature below 250° C., for a predetermined time. Such an annealing, i.e., heating, of the substrate together with the metal layer has been found to gradually relax the compressive properties, until at higher temperature tensile properties as shown in FIG. 3 would be reached. When heating at lower temperatures, e.g., below 250° C., and/or for limited periods of time, the compressive properties may be sufficiently relaxed to limit the stress to desired values.

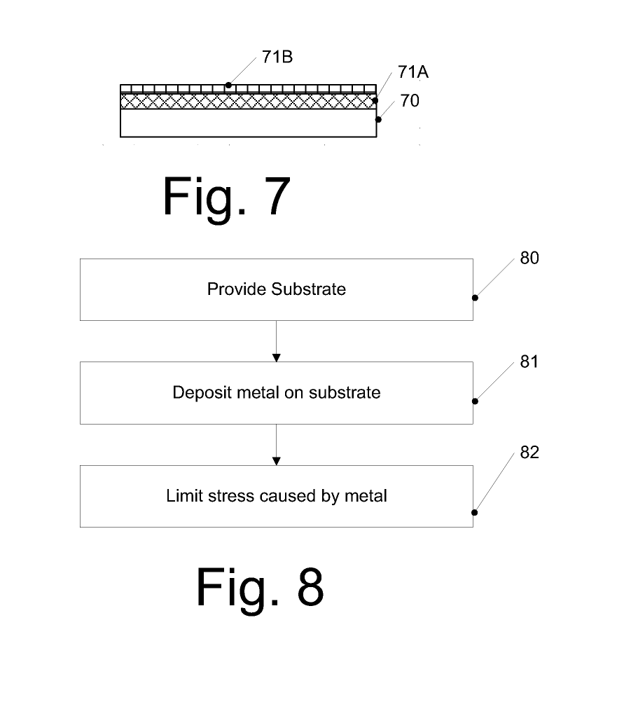

In yet further embodiments a first metal sublayer may be deposited in the first pressure range followed by a second metal sublayer in the second pressure range or vice versa, such that the stress exerted by the two metal sublayers is compensated. In other words, the thicknesses of the sublayers are selected such that the tensile stress exerted by the metal sublayer deposited in the first pressure range at least partially compensates the stress exerted by the metal sublayer deposited in the second pressure range. An embodiment of a corresponding substrate with a metal layer is schematically shown in FIG. 7.

In FIG. 7, two metal sublayers 71A, 71B are deposited on a substrate 70. Substrate 70 for example may be a silicon wafer, and metal sublayers 71A, 71B may for example be copper layers deposited by sputtering. In an embodiment, sublayer 71A may be deposited under a condition as shown in FIGS. 2 and 3 causing tensile stress to substrate 70, and metal sublayer 71B may be deposited under a condition in the second pressure range as shown in FIGS. 4 and 5, thus causing compressive stress to substrate 17. The tensile stress caused by sublayer 71A and the compressive stress caused by sublayer 71B at least partially cancel each other out, thus leading to a limited overall stress and a reduced (or minimized) bending of substrate 70.

It should be noted that sublayers 71A, 71B may have the same thickness or different thicknesses, depending on the conditions and the stress caused by each respective sublayer. Also, embodiments are not limited to two metal sublayers, but also more than two sublayers are possible. For example, the structure of FIG. 7 with sublayers 71A and 71B may be repeated several times. Also, an odd number of sublayers may be used, for example three sublayers, with for example a sublayer causing one type of stress (tensile or compressive) being sandwiched between two sublayers causing the other type of stress (tensile or compressive). Also, the order of the sublayers causing compressive and tensile stress, respectively, may be reversed. For example, in an embodiment sublayer 71A may be deposited in the second pressure range thus causing compressive stress, and sublayer 71B may be deposited in the first pressure range, thus causing tensile stress. Therefore, definitions like “comprising a first sublayer causing a first type of stress and a second sublayer causing a second type of stress” are not to be construed as indicating any particular order or number of the respective sublayers.

Next, with reference to FIGS. 8 and 11 various methods according to embodiments will be discussed. For illustration purposes, and to provide a better understanding, the methods will be described using the devices and techniques already described above as examples. However, it is to be emphasized that the embodiments of FIGS. 8-11 may be implemented independent from the embodiments and techniques discussed with reference to FIGS. 1-7.

Turning now to FIG. 8, at 80 in FIG. 8 a substrate is provided. The substrate may for example be a semiconductor wafer, in particular a thinned semiconductor wafer, for example a thinned semiconductor wafer thinned to a thickness below 100 μm, e.g., about 60 μm, or a regular semiconductor wafer having a thickness for example between 400 and 1000 μm. The semiconductor wafer may for example be a silicon wafer, but is not limited thereto. In other embodiments, other kinds of substrates may be used.

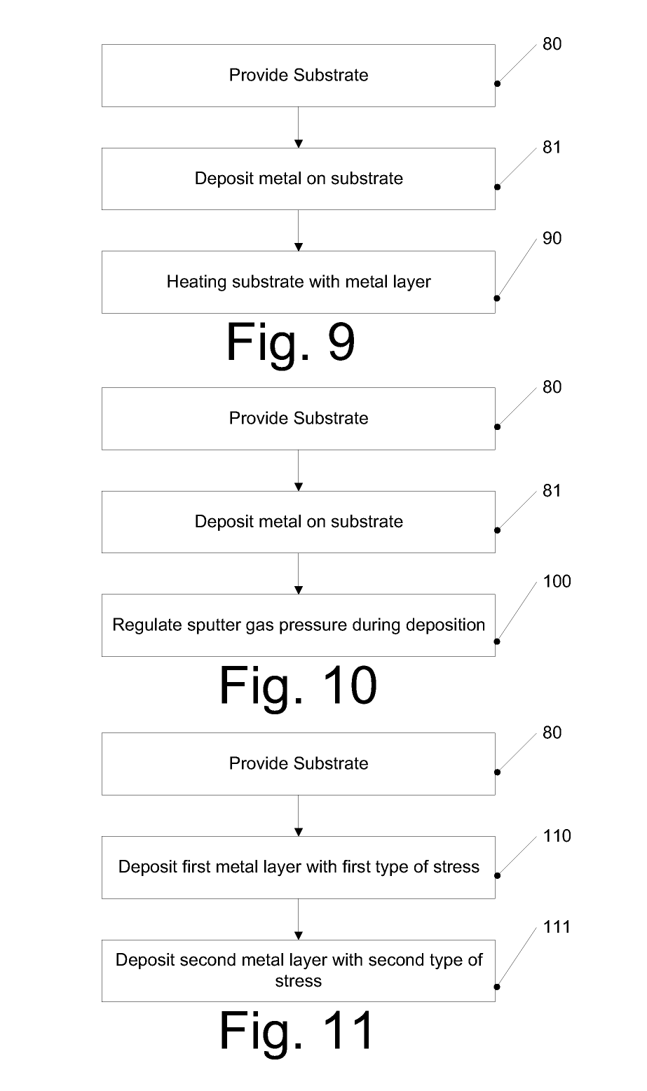

At 81, metal is deposited on the substrate which is provided at 80. The metal may for example be copper, but may also be another metal like aluminum, tin, gold or silver. However, it is to be understood that the method of FIG. 8 is not limited to these metals, and other metals also may be used. The metal may for example be deposited on a backside of the provided substrate, while on the front side for example semiconductor devices may be formed. In other embodiments, additionally or alternatively, the metal may be deposited on the front side. The metal may for example be deposited by sputtering, for example as explained previously with respect to FIGS. 2 and 4. However, other metal deposition techniques also may be used. At 82, stress to the substrate which is caused by the metal deposited on the substrate is limited, for example limited such that bending caused by the stress is less than 0.002 times the wafer diameter or 0.001 times the wafer diameter. The limiting of the stress may be obtained by setting appropriate process parameters like sputter gas pressure during the metal deposition or may be achieved by treating the deposited metal on the substrate after the deposition, for example by heating. Embodiments comprising specific examples of limiting the stress will now be explained with reference to FIGS. 9-11.

In the embodiment of FIG. 9, at 80 a substrate is provided, and at 81 metal is deposited on the substrate, as has already been described with reference to FIG. 8. In the embodiment of FIG. 9, at 81 the metal may be deposited by sputtering in the second pressure range (see FIGS. 4 and 5), thus causing compressive stress to the substrate. At 90, to reduce the stress caused by the metal, the substrate with the metal layer deposited thereon may be heated, for example to partially relax the metal to reduce compressive stress. For example, in case the metal layer is a copper layer deposited in the second temperature range, the heating may be performed at temperatures below 250° C.

A further method according to an embodiment is shown in FIG. 10. Again, at 80 a substrate is provided, and at 81 metal is deposited on the substrate, as already explained with reference to FIG. 8. In case of the embodiment of FIG. 10, metal is deposited via sputtering, as explained with reference to FIGS. 2 and 4. To limit the stress caused by the metal, at 100 the sputter gas pressure is regulated during deposition, for example to a pressure value between the first pressure range and the second pressure range explained previously, for example to a pressure of the order of 0.3 mTorr, to obtain a metal layer which causes reduced stress to the substrate. In other embodiments, the sputter gas pressure may be varied during deposition, for example to deposit alternating metal sublayers causing compressive stress and tensile stress, respectively.

It should be noted that the embodiment of FIG. 10 is an example where the limiting of the stress (through regulating the sputter gas pressure at 100) is performed concurrently with the metal deposition, while the embodiment of FIG. 9 is an example where the limiting of the stress (by heating) is preformed after the metal deposition.

In FIG. 11, a further embodiment of a method is schematically shown. At 80, a substrate is provided, as already explained with reference to FIG. 8. At 110, a first metal sublayer causing a first type of stress, for example causing one of tensile stress and compressive stress to the substrate, is deposited, for example by selecting the pressure range of sputter gas during sputtering accordingly. At 111, a second metal sublayer causing a second type of stress, for example causing the other of tensile stress and compressive stress to the substrate, is deposited. As already explained with reference to FIG. 7, also more than two layers causing different stress to the substrate may be deposited successively.

The various techniques described above may be combined with each other unless specifically noted otherwise.

As can be seen, numerous modifications and variations are possible within the scope of the present application, and therefore the examples and embodiments described above are intended to merely illustrate implementation possibilities and are not construed as limiting the scope.

What is claimed is:

1. A method, comprising:
providing a substrate;
depositing a metal on the substrate; and
limiting stress caused by the metal deposited on the substrate.

2. The method of claim 1, wherein the substrate comprises a semiconductor substrate.

3. The method of claim 1, wherein the metal comprises a material selected from the group consisting of copper, tin, gold, silver and aluminum.

4. The method of claim 1, wherein depositing the metal comprises sputtering the metal.

5. The method of claim 1, wherein the limiting stress comprises regulating at least one process parameter during the deposition of metal to limit the stress.

6. The method of claim 5, wherein depositing the metal comprises sputtering the metal and wherein regulating the process parameter comprises regulating a sputter gas pressure.

7. The method of claim 6, wherein regulating the sputter gas pressure comprises regulating the sputter gas pressure to a pressure between a first pressure range in which the metal causes tensile stress to the substrate and a second pressure range where the metal causes compressive strain to the substrate.

8. The method of claim 6, wherein regulating the sputter gas pressure comprises alternatingly regulating the sputter gas pressure to a first pressure range where the metal causes tensile stress and to a second pressure range where the metal causes compressive stress so as to alternatingly deposit metal sublayers causing tensile stress and compressive stress.

9. The method of claim 1, wherein the limiting stress comprises heating the substrate with the metal deposited thereon.

10. The method of claim 9, wherein the heating the substrate comprises heating to a temperature at or below 250° C.

11. A method, comprising:
providing a substrate;
depositing a first metal sublayer causing a first type of stress to the substrate; and
depositing a second metal sublayer causing a second type of stress different from the first type of stress to the substrate.

12. The method of claim 11, wherein the first type of stress is one of tensile stress and compressive stress and the second type of stress is the other one of tensile stress and compressive stress.

13. The method of claim 11, wherein the first metal sublayer and the second metal sublayer are made of the same metal.

14. A device, comprising:
a substrate;
a first metal sublayer on the substrate, the first metal sublayer causing a first type of stress to the substrate; and
a second metal sublayer on the first metal sublayer, the second metal sublayer causing a second type of stress that is different from the first type of stress to the substrate.

15. The device of claim 14, wherein the substrate is a semiconductor substrate, and wherein the first metal sublayer and the second metal sublayer are disposed on a backside of the semiconductor substrate.

16. The device of claim 14, wherein the first type of stress is one of tensile stress or compressive stress and the second type of stress is the other one of tensile stress and compressive stress.

17. A device, comprising:
a substrate; and
a metal layer on the substrate,
wherein a thickness of the substrate is less than 100 μm; and
wherein a bending of the substrate is less than 0.002 times a diameter of the substrate.

18. The device of claim 17, wherein the substrate is a silicon substrate and wherein the metal layer is a copper layer on a backside of the silicon substrate.

19. An apparatus, comprising:
a sputter chamber,
a metal target;
a sputter gas inlet; and
a control unit, wherein the control unit is configured to control a pressure of the sputter gas within the sputter chamber to limit stress caused by metal deposited on a substrate.

20. The apparatus of claim 19, wherein the control unit is configured to regulate the sputter gas pressure to a value between a first pressure range where the metal causes tensile stress and a second pressure range where the metal causes compressive stress.

21. The apparatus of claim 19, wherein the control unit is configured to regulate the sputter gas pressure alternatingly to a pressure in a first pressure range where the metal causes tensile stress and a second pressure range where the metal causes compressive stress so as to alternatingly deposit metal sublayers causing tensile stress and causing compressive stress.

22. The apparatus of claim 19, wherein the metal target comprises copper and wherein the sputter gas comprises Argon.
